(19) United States
(12) Patent Application Publication
(10) Pub. No.: US 2025/0126867 A1
(43) Pub. Date: Apr. 17, 2025

(54) INTERFACIAL LAYER SCALING PROCESSES FOR SEMICONDUCTOR DEVICES

(71) Applicant: Applied Materials, Inc., Santa Clara, CA (US)

(72) Inventors: Srinivas Gandikota, Santa Clara, CA (US); Yixiong Yang, Fremont, CA (US); Seshadri Ganguli, San Jose, CA (US); Geetika Bajaj, Cupertino, CA (US); Debaditya Chatterjee, Sunnyvale, CA (US); Hsin-Jung Yu, Santa Clara, CA (US); Tuerxun Ailihumaer, Santa Clara, CA (US); Tengzhou Ma, San Jose, CA (US); Lin Sun, Milpitas, CA (US)

(73) Assignee: Applied Materials, Inc., Santa Clara, CA (US)

(21) Appl. No.: 18/379,928

(22) Filed: Oct. 13, 2023

(51) Int. Cl. H01L 29/40; H01L 21/324; H01L 29/49; H01L 29/51

(52) U.S. Cl. CPC H10D 64/01; H01L 21/324; H10D 64/667; H10D 64/685; H10D 64/691

(57) ABSTRACT

Methods of scaling the thickness of the interfacial layer in electronic devices, such as NMOS transistors and PMOS transistors are described. Some embodiments provide a metal film or a metal nitride film that reduces the thickness of the interfacial layer by scavenging unbound oxygen from the interfacial layer (e.g., silicon oxide (SiOx)) and the high-κ dielectric layer (e.g., hafnium oxide (HfOx)). Some embodiments advantageously include annealing the semiconductor substrate to promote or accelerate the scavenging.

### TECHNICAL FIELD

Embodiments of the present disclosure pertain to the field of electronic device manufacturing, and in particular, to transistors. More particularly, embodiments of the disclosure are directed to methods of scaling interfacial layer thickness in NMOS transistors and PMOS transistors.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate planar field-effect transistors (FETs) in which current flows through a semiconducting channel between a source and a drain, in response to a voltage applied to a control gate.

As device dimensions have shrunk, device geometries and materials have experienced difficulty maintaining switching speeds without incurring failures. Several new technologies emerged that allowed chip designers to continue shrinking gate lengths. Control of the dimensions of device structure is a key challenge for present and future technology generations.

Shrinking of the materials currently used as negative metal-oxide-semiconductor (NMOS) transistors and positive metal-oxide-semiconductor (PMOS) transistors have become a challenge throughout the migration of transistor technology from planar FET to FinFET to gate all-around (GAA) devices.

The reduction of dielectric thickness in NMOS transistors and PMOS transistors is crucial to scaling the gate length and for the progress of semiconductor technology for future generations. With the reduction of the thickness of the conventional oxide/oxynitride dielectric layer in MOSFETs, there is an exponential increase in gate leakage which, in turn, results in an increased power consumption of the device. Moreover, the thickness of the dielectric is now close to a few atomic layers, raising reliability concerns.

Gate stacks including a high-κ gate dielectric, i.e., dielectrics having a dielectric constant that is greater than silicon oxide, and an overlying metal gate are being used to replace conventional gate stacks including silicon oxide and polysilicon to enable transistor scaling. In high-κ/metal gate stacks there is typically an interfacial layer (typically silicon dioxide) present between the high-κ dielectric and the underlying semiconductor substrate.

The capacitance of the interfacial layer limits the overall scalability of the gate stacks and acts as a bottleneck in gate stack scaling. While removal of the interfacial layer is possible, the same results in severe carrier mobility penalty, and, for example, leakage, and challenges with turning transistors on and off.

Accordingly, there is a need for improved methods of scaling the thickness of the interfacial layer, to provide electronic devices having reduced capacitance, and thereby, reduced equivalent oxide thickness (EOT).

### SUMMARY

One or more embodiments of the disclosure are directed to a method of manufacturing an electronic device. The method comprises: depositing an interfacial layer on a top surface of a channel located between a source and a drain on a semiconductor substrate; depositing a high-κ dielectric layer on the interfacial layer; depositing a titanium nitride (TiN) layer on the high-κ dielectric layer; depositing a metal film or a metal nitride film on the titanium nitride (TiN) layer; and depositing a capping layer on the metal film or the metal nitride film.

Additional embodiments of the disclosure are directed to a method of manufacturing an electronic device. The method comprises: depositing an interfacial layer comprising silicon oxide (SiOx) and a thickness in a range of from 8 Å to 11 Å on a top surface of a channel located between a source and a drain on a semiconductor substrate; depositing a high-κ dielectric layer comprising hafnium oxide (HfOx) and a thickness in a range of from 10 Å to 20 Å on the interfacial layer; depositing a titanium nitride (TiN) layer on the high-κ dielectric layer; depositing a metal film or a metal nitride film on the titanium nitride (TiN) layer. In some embodiments, the metal film or the metal nitride film includes a multilayer film. The multilayer film reduces the thickness of the interfacial layer by scavenging unbound oxygen from the interfacial layer and the high-κ dielectric layer. The method further comprises: depositing a capping layer comprising amorphous silicon (a-Si) and a thickness in a range of 0 Å to 20 Å on the metal film or the metal nitride film; and annealing the semiconductor substrate at a temperature of less than or equal to 1050° C. to accelerate the scavenging.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method of manufacturing an electronic device according to one or more embodiments of the present disclosure;

FIG. 2A illustrates a cross-sectional view of a semiconductor substrate according to one or more embodiments of the present disclosure;

FIG. 2B illustrates a cross-sectional view of a semiconductor substrate according to one or more embodiments of the present disclosure;

FIG. 2C illustrates a cross-sectional view of a semiconductor substrate according to one or more embodiments of the present disclosure;

FIG. 2D illustrates a cross-sectional view of a semiconductor substrate according to one or more embodiments of the present disclosure;

FIG. 2E illustrates a cross-sectional view of a semiconductor substrate according to one or more embodiments of the present disclosure;

FIG. 2F illustrates a cross-sectional view of a semiconductor substrate according to one or more embodiments of the present disclosure; and

FIG. 3 illustrates a cluster tool according to one or more embodiments of the present disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of +15%, or less, of the numerical value. For example, a value differing by +14%, +10%, +5%, +2%, or +1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the electronic device in use or operation in addition to the orientation depicted in the figures. For example, if the electronic device in the Figures is turned over, elements described as “below” or “beneath” other elements would then be oriented “above” the other elements. Thus, the exemplary term “below” may encompass both an orientation of above and below. The electronic device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor,” “reactant,” “reactive gas,” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate, such as a semiconductor substrate, and exhibit a doping profile suitable for a particular application. The gate is positioned over the channel region and includes a gate dielectric interposed between a gate electrode and the channel region in the semiconductor substrate.

As used herein, the term “field effect transistor” or “FET” refers to a transistor that uses an electric field to control the electrical behavior of the device. Field effect transistors are voltage controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated ID. Drain-to-source voltage is designated VDs. By applying voltage to gate (G), the current entering the channel at the drain (i.e. ID) can be controlled.

The metal-oxide-semiconductor field-effect transistor (MOSFET) is a type of field-effect transistor (FET) and is used in integrated circuits and high speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or NMOS FET, then the source and drain are n+ regions and the body is a p-type substrate region. If the MOSFET is a p-channel or PMOS FET, then the source and drain are p+ regions and the body is an n-type substrate region. The source is so named because it is the source of the charge carriers (electrons for n-channel, holes for p-channel) that flow through the channel; similarly, the drain is where the charge carriers leave the channel.

A NMOS FET is made up of an n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode and saturation. Circuits with NMOS logic gates dissipate static power when the circuit is idling, since DC current flows through the logic gate when the output is low.

A PMOS FET is made up of p-type source and drain and an n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said to have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices.

Furthermore, NMOS ICs would be smaller than PMOS ICs (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nanoslabs or nanosheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10-9 meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

Embodiments of the present disclosure advantageously provide methods of manufacturing electronic devices that have improved device performance and reliability. Some embodiments advantageously provide methods of scaling the thickness of the interfacial layer to provide electronic devices having reduced capacitance, and thereby, reduced equivalent oxide thickness (EOT). Some embodiments provide methods of scaling the thickness of the interfacial layer to provide electronic devices having reduced leakage (Jg).

Some embodiments advantageously provide a metal film or a metal nitride film that reduces the thickness of the interfacial layer by scavenging unbound oxygen from the interfacial layer (e.g., silicon oxide (SiOx)) and the high-κ dielectric layer (e.g., hafnium oxide (HfOx)). Some embodiments advantageously include annealing the semiconductor substrate to promote or accelerate the scavenging.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

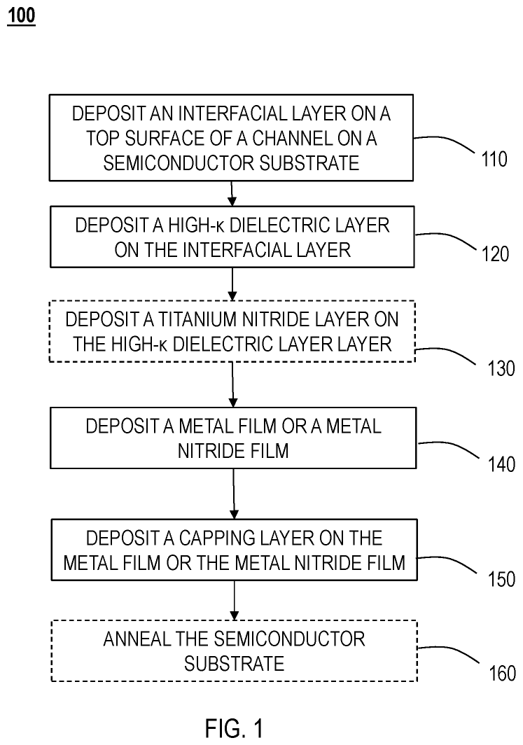

FIG. 1 illustrates a process flow diagram of a method 100 of manufacturing an electronic device according to one or more embodiments of the present disclosure.

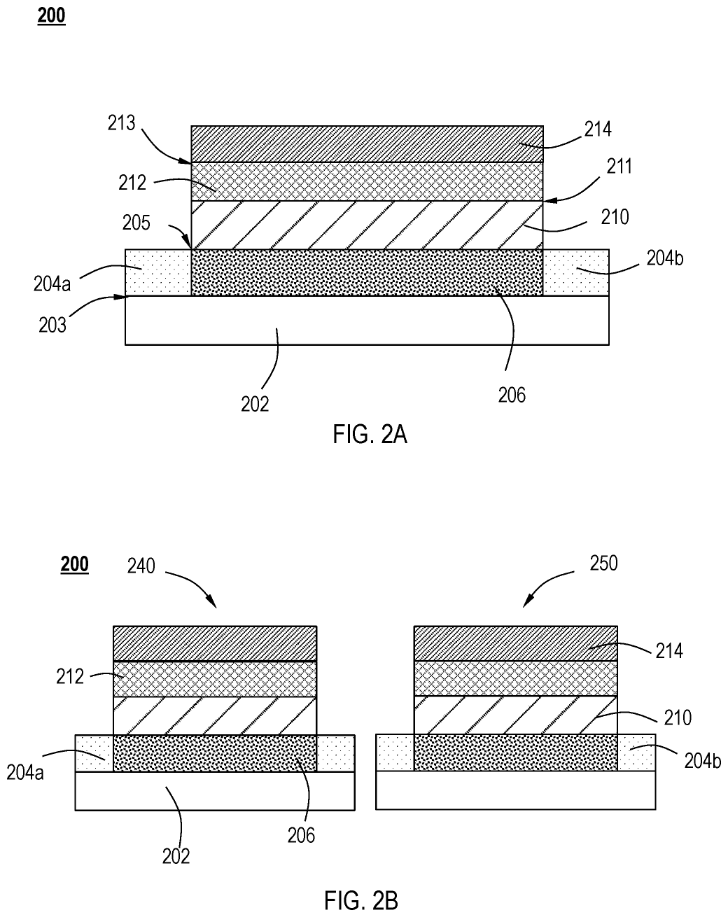

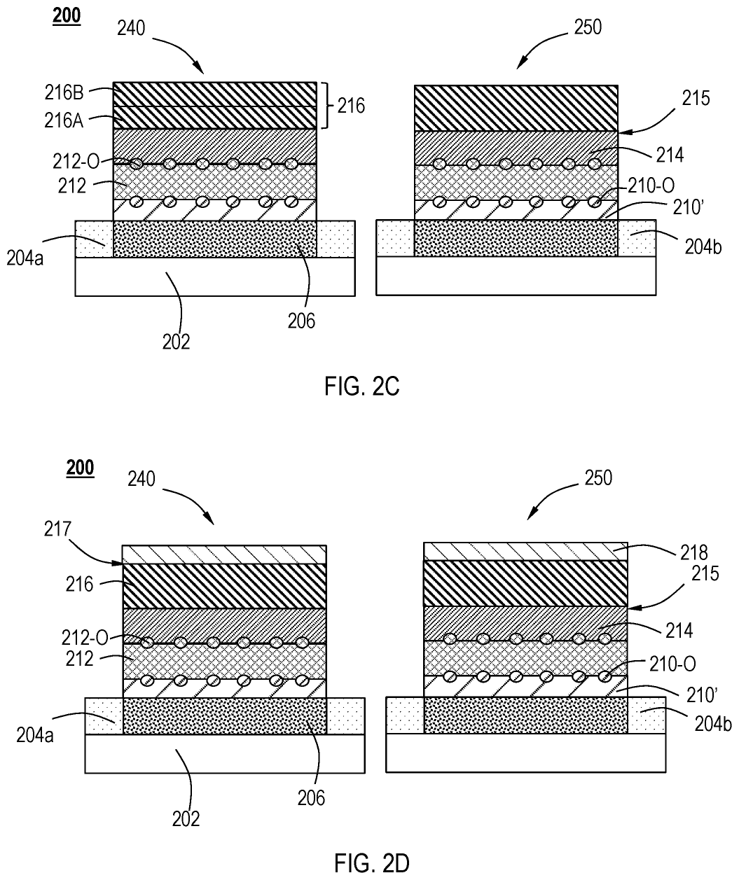

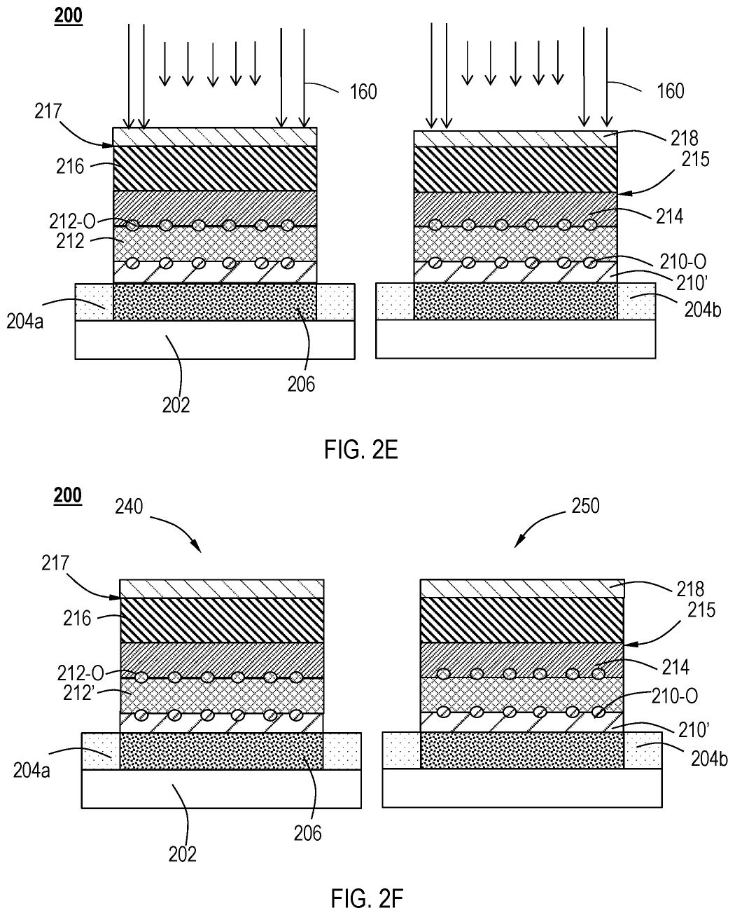

FIG. 2A-2F are cross-sectional views of an electronic device (e.g., a transistor such as a FinFET or GAA) 200 according to one or more embodiments. The electronic devices 200 shown in FIGS. 2A-2F may be manufactured by the method 100 illustrated in FIG. 1.

In one or more embodiments, the method 100 comprises depositing an interfacial layer 210 on a top surface 205 of a channel 206 located between a source 204a and a drain 204b on a semiconductor substrate 202 (operation 110); depositing a high-κ dielectric layer 212 on the interfacial layer 210 (operation 120); optionally, depositing a titanium nitride (TiN) layer 214 on the high-κ dielectric layer 212 (operation 130); depositing a metal film or a metal nitride film 216 on the titanium nitride (TiN) layer 214 (if present) (operation 140); depositing a capping layer 218 on the metal film or the metal nitride film 216 (operation 150); and annealing the semiconductor substrate 202 at a temperature of less than or equal to 1050° C. (optional operation 160). In one or more embodiments, the method 100 consists essentially of operation 110, operation 120, operation 130, operation 140, operation 150, and operation 160. In one or more embodiments, the method 100 consists of operation 110, operation 120, operation 130, operation 140, operation 150, and operation 160.

The semiconductor substrate 202 can be any suitable substrate material. In one or more embodiments, the semiconductor substrate 202 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the semiconductor substrate 202 comprises one or more of silicon (Si), germanium (Ge), gallium (Ga), arsenic (As), indium (In), phosphorus (P), or selenium (Se). In one or more embodiments, the semiconductor substrate 202 comprises silicon (Si). Although a few examples of materials from which the semiconductor substrate 202 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one or more embodiments, the semiconductor substrate 202 is a p-type or n-type substrate. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In one or more embodiments, a source region 204a is on the top surface 203 of the semiconductor substrate 202. In one or more embodiments, the source region 204a has a source and a source contact. A drain region 204b is on the top surface 203 of the semiconductor substrate 202 opposite the source region 204a. In one or more embodiments, the drain region 204b has a drain and a drain contact.

In one or more embodiments, the source region 204a and/or the drain region 204b can be any suitable material known to the skilled artisan. In one or more embodiments, the source region 204a and/or the drain region 204b may have more than one layer. For example, the source region 204a and/or the drain region 204b may independently comprise three layers. In one or more embodiments, the source region 204a and the drain region 204b may independently comprise one or more of copper (Cu), cobalt (Co), tungsten (W), titanium (Ti), molybdenum (Mo), nickel (Ni), ruthenium (Ru), silver (Ag), gold (Au), iridium (Ir), platinum (Pt), phosphorus (P), germanium (Ge), silicon (Si), aluminum (AI), or zirconium (Zr). In some embodiments, the source region 204a and the drain region 204b may independently comprise a bottom layer of silicon with doped epi (e.g., SiGe, SiP, and the like), a second layer of silicide, which may contain nickel (Ni), titanium (Ti), aluminum (AI), and the like, and a third, or top, layer which may be a metal such as, but not limited to, cobalt, tungsten, ruthenium, and the like. In some embodiments, the source region 204a and the drain region 204b may be raised source/drain regions formed by EPI growth.

In one or more embodiments, the source contact and/or the drain contact may independently be a metal selected from one or more of a copper (Cu), cobalt (Co), tungsten (W), titanium (Ti), molybdenum (Mo), nickel (Ni), ruthenium (Ru), silver (Ag), gold (Au), iridium (Ir), tantalum (Ta), zirconium (Zr), lanthanum (La), yttrium (Y), ytterbium (Yb), scandium (Sc), erbium (Er), platinum (Pt), palladium (Pd), nitrides thereof, alloys thereof, and/or silicides thereof. In one or more embodiments, formation of the source contact and/or the drain contact is conducted by any suitable process known to the skilled artisan, including, but not limited to ALD, CVD, PVD, MBE, MOCVD, spin-on, or other insulating layer deposition techniques known to the skilled artisan.

In one or more embodiments, a channel 206 is located between the source 204a and the drain 204b. In some embodiments, such as when the electronic device 200 is a GAA device, the channel 206 comprises a plurality of nanosheets. The channel 206 may include any suitable material known to the skilled artisan. In one or more embodiments, the channel 206 comprises silicon (Si).

In one or more embodiments, at operation 110, an interfacial layer 210 is deposited on the top surface 205 of the channel 206 using a deposition technique, such as, but not limited to, ALD, CVD, PVD, MBE, MOCVD, spin-on, or other insulating layer deposition techniques known to the skilled artisan. In one or more embodiments, the interfacial layer 210 is continuous.

In one or more embodiments, the interfacial layer 210 comprises silicon oxide (SiOx). In some embodiments, the interfacial layer 210 comprises silicon oxide (SiOx) and the semiconductor substrate 202 comprises doped silicon or undoped silicon. In some embodiments, the interfacial layer 210 comprises silicon dioxide (SiO₂). In some embodiments, the interfacial layer 210 may be formed by etching and an oxide forming on the semiconductor substrate 202 surface, such as, for example, a silicon (Si) surface or silicon germanium (SiGe) surface.

In some embodiments, at operation 110, a wet chemistry technique is performed to form the interfacial layer 210. The wet chemistry technique may be any suitable technique known to the skilled artisan. In some embodiments, the wet chemistry technique includes a pre-clean process. In some embodiments, the pre-clean process includes using a SC-1 solution comprising one or more of ozone, ammonium hydroxide or hydrogen peroxide. In some embodiments, the pre-clean process includes using a SC-1 solution without ozone, ammonium hydroxide or hydrogen peroxide. In some embodiments, after using the SC-1 solution, the pre-clean process includes using dilute hydrofluoric acid (dilute HF), including greater than 100:1, such as 130:1 dilute HF, to etch away native oxide on the semiconductor substrate 202 to form a hydrophobic surface (i.e., the interfacial layer 210).

In some embodiments, at operation 110, a rapid thermal process (RTP) is used to form the interfacial layer 210. The RTP may be any suitable process known to the skilled artisan. In some embodiments, at operation 110, the RTP is a thermal oxidation process in which the interfacial layer 210, e.g., a silicon oxide (SiOx) layer, is grown on the semiconductor substrate 202.

The interfacial layer 210 may have any suitable thickness. The thickness of the interfacial layer 210 depends on the specific application in which the interfacial layer 210 is being used. For example, in one or more embodiments, the thickness of interfacial layer 210 depends on the capacitance equivalent thickness (CET) of the particular electronic device. In other embodiments, the thickness of interfacial layer 210 depends on the thickness needed to form another layer on the interfacial layer 210, such as, for example, a high-κ dielectric layer 212. In one or more embodiments, the interfacial layer 210 has a thickness in a range of from 8 Å to 11 Å, such as in a range of from 10 Å to 11 Å.

In one or more embodiments, at operation 120, the high-κ dielectric layer 212 is deposited on a top surface 211 of the interfacial layer 210 using a deposition technique, such as, but not limited to, ALD, CVD, PVD, MBE, MOCVD, spin-on, or other insulating layer deposition techniques known to the skilled artisan. In some embodiments, at operation 120, the high-κ dielectric layer 212 is conformally deposited by ALD.

In some embodiments, the high-κ dielectric layer 212 comprises one or more of hafnium oxide (HfOx), hafnium zirconium oxide (HfZrOx), zirconium oxide (ZrOx), nitrogen-doped hafnium oxide (HfOx), nitrogen-doped hafnium zirconium oxide (HfZrOx), and nitrogen-doped zirconium oxide (ZrOx). In some embodiments, the high-κ dielectric layer 212 comprises hafnium oxide (HfOx).

In one or more embodiments, the high-κ dielectric layer 212 is continuous and covers an entire exposed surface (e.g., the interfacial layer 210) without gaps or bare spots that reveal material underlying the high-κ dielectric layer 212.

The high-κ dielectric layer 212 may have any suitable thickness such that the high-κ dielectric layer 212 remains continuous, as described herein, and prevents etching of the interfacial layer 210 during subsequent operations. In one or more embodiments, the high-κ dielectric layer 212 has a thickness in a range of from 10 Å to 20 Å, such as in a range of from 12 Å to 20 Å.

In some embodiments, at operation 130, the titanium nitride (TiN) layer 214 is optionally deposited on a top surface 213 of the high-κ dielectric layer 212 using a deposition technique, such as, but not limited to, ALD, CVD, PVD, MBE, MOCVD, spin-on, or other insulating layer deposition techniques known to the skilled artisan. In one or more embodiments, the titanium nitride (TiN) layer 214 is not continuous. In one or more embodiments, the titanium nitride (TIN) layer 214 has gaps or bare spots that reveal material underlying the titanium nitride (TiN) layer 214, e.g., the high-κ dielectric layer 212. In one or more embodiments, the titanium nitride (TiN) layer 214 having a thickness of less than or equal to 10 Å is not continuous.

In some embodiments, at operation 130, depositing the titanium nitride (TIN) layer 214 comprises exposing the semiconductor substrate 202 to a pulse of a titanium-containing precursor and a pulse of a reactant, such as a nitrogen-containing reactant, by an atomic layer deposition (ALD) process or a chemical vapor deposition (CVD) process. In some embodiments, the semiconductor substrate 202 is purged after each pulse.

The titanium-containing precursor may be any suitable precursor that includes titanium and the nitrogen-containing reactant may be any suitable reactant that includes nitrogen.

In some embodiments, the titanium-containing precursor comprises titanium tetrachloride (TiCl₄), titanium tetraiodide (TiI₄), titanium tetrafluoride (TiF₄), titanium tetrabromide (TiBr₄), or tetrakis(dimethylamido) titanium (TDMAT). In some embodiments, the nitrogen-containing reactant comprises one or more of nitrogen (N₂), ammonia (NH₃), hydrazine (N₂H₄), a co-flow of nitrogen radicals (N₂*) and hydrogen radicals (H*), a co-flow of nitrogen radicals (N₂*) and hydrogen (H₂) gas, or a co-flow of nitrogen radicals (N₂*) and deuterium (²H) gas.

In some embodiments the nitrogen-containing reactant comprises a substituted or unsubstituted alkyl hydrazine. In some embodiments, the alkyl hydrazine comprises in a range of from 1 carbon to 6 carbons. In one or more embodiments, the alkyl hydrazine is t-butyl hydrazine. In some embodiments, the nitrogen-containing reactant comprises a plasma. In some embodiments, the nitrogen-containing reactant comprises ammonia (NH₃).

The titanium nitride (TiN) layer 214 may have any suitable thickness. In one or more embodiments, the titanium nitride (TiN) layer 214 has a thickness in a range of from 0 Å to 10 Å, such as in a range of from 5 Å to 10 Å.

In FIGS. 2B-2F, an N-metal stack 240 and a P-metal stack 250 are shown. In one or more embodiments, the stack on the left side of FIG. 2B is the N-metal stack 240 and the stack on the right side of FIG. 2B is the P-metal stack 250. The skilled artisan recognizes that the either the left side or the right side may comprise either of the N-metal stack or the P-metal stack, and the disclosure is not limited to the illustrated embodiments of FIGS. 2B-2F. In one or more embodiments, the N-metal stack 240 and the P-metal stack 250 may have the desired dipole set using a process known to the skilled artisan.

FIGS. 1 and 2C illustrate deposition of the metal film or the metal nitride film 216 on the titanium nitride (TIN) layer 214 (operation 140). As used herein, the reference numeral 216 may be used to refer to one of the metal film or the metal nitride film individually, or to the metal film and the metal nitride film collectively.

The metal film may include any suitable metal and the metal nitride film may include any metal nitride. The metal film and/or the metal nitride film 216 may include any electropositive metal. In one or more embodiments, the electronic device 200 includes a metal film 216 selected from one or more of titanium (Ti), aluminum (Al), germanium (Ge), tantalum (Ta), zirconium (Zr), strontium (Sr), barium (Ba), or a lanthanide series metal (e.g., a lanthanide from the Periodic Table of Elements). In some embodiments, the electronic device 200 includes a metal film 216 selected from one or more of titanium (Ti), aluminum (Al), or germanium (Ge).

In one or more embodiments, the electronic device 200 includes a metal nitride film 216 selected from one or more of titanium nitride (TiN), aluminum nitride (AlN), germanium nitride (GeN), tantalum nitride (TaN), zirconium nitride (ZrN), strontium nitride (SrN), barium nitride (BaN), or a nitride of a lanthanide series metal. In some embodiments, the electronic device 200 includes a metal nitride film 216 selected from one or more of titanium nitride (TiN), aluminum nitride (AlN), or germanium nitride (GeN).

In one or more embodiments, the metal film 216 comprising titanium (Ti) is formed by ALD using a titanium-containing precursor and a reactant. The reactant may be any suitable reactant that reacts with the titanium-containing precursor to form a metal film comprising titanium (Ti).

In one or more embodiments, the reactant comprises diethylzinc (DEZ). In one or more embodiments the reactant is an organosilane reducing agent comprising a compound of general formula (II) or general formula (III)

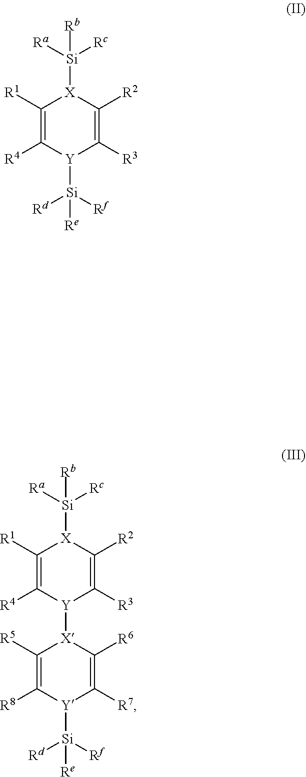

wherein R¹, R², R³, R⁴, R⁵, R⁶, R⁷, R⁸, R^{a}, R^{b}, R^{c}, R^{d}, R^{e}, and R^{f} are independently selected from hydrogen (H), substituted alkyl or unsubstituted alkyl; and X, Y, X′, and Y′ are independently selected from nitrogen (N) and carbon (C).

In one or more embodiments, the organosilane reducing agent comprises one or more of bis(trimethylsilyl)cyclohexadiene, bis(trimethylsilyl)diaza-cyclohexadiene, bis(trimethylsilyl) aza-cyclohexadiene, bis(trimethylsilyl)-dihydro-bipyridine, 3,6-bis(trimethylsilyl)-1,4-cyclohexadiene, 1-methyl-3,6-bis(trimethylsilyl)-1,4-cyclohexadiene, and 1,4-bis-(trimethylsilyl)-1,4-diaza-2,5-cyclohexadiene.

In one or more embodiments, the reactant comprises 1-methyl-3,6-bis(trimethylsilyl)-1,4-cyclohexadiene

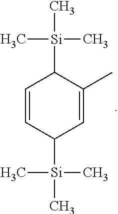

In one or more embodiments, the reactant comprises:

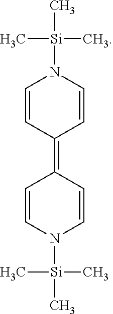

In one or more embodiments, the reactant comprises

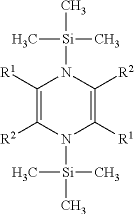

wherein R¹ and R² are independently selected from hydrogen (H), substituted alkyl or unsubstituted alkyl. In one or more embodiments, R₁ and R₂ are the same. In one or more embodiments, R₁ and R₂ are different. In one or more embodiments, each R₁ and R₂ are hydrogen. In one or more embodiments, each R₁ and R₂ are methyl. In one or more embodiments, at least one R₁ is methyl and at least one R₂ is hydrogen. In one or more embodiments, each R₁ is methyl and each R₂ is hydrogen.

The metal film 216 comprising titanium (Ti) can be formed at any suitable processing conditions. In one or more embodiments, the metal film 216 comprising titanium (Ti) can be formed at any suitable pressure, temperature, reactant pulse/purge time, and reactant flow rate. Advantageously, forming the metal film 216 by ALD using a titanium-containing precursor comprising titanium tetrachloride (TiCl₄), purge, a reactant comprising, for example, 1-methyl-3,6-bis(trimethylsilyl)-1,4-cyclohexadiene, and purge, produces pure titanium (Ti) film that is substantially free of chlorine (CI) and carbon (C). As used in this regard, “substantially free” means that less than about 10 at. %, less than about 5 at. %, including less than about 4 at. %, less than about 3 at. %, less than about 2 at. %, less than about 1 at. %, less than about 0.5 at. %, and less than about 0.1 at. % of the total composition of the conformally deposited titanium (Ti) film, on an atomic basis, comprises chlorine (CI) and/or carbon (C).

In one or more embodiments, the metal film and/or the metal nitride film 216 is formed at a pressure in a range of from about 1 Torr to about 30 Torr. In one or more embodiments, the metal film and/or the metal nitride film 216 is formed at a temperature in a range of from about 150° C. to about 450° C., such as, for example, in a range of from about 150° C. to about 300° C. In one or more embodiments, the reactant pulse time is in a range of from about 2 seconds to about 6 seconds. In one or more embodiments, the reactant purge time is in a range of from about 4 seconds to about 10 seconds. In one or more embodiments, the reactant flow rate is in a range of from about 200 sccm to about 800 sccm.

The metal film or the metal nitride film 216 may be formed using any suitable metal-containing precursor including, but not limited to, one or more of titanium (Ti), aluminum (AI), germanium (Ge), tantalum (Ta), zirconium (Zr), strontium (Sr), barium (Ba), or a lanthanide series metal. In one or more embodiments, a metal organic precursor is used to form the metal film 216. In one or more embodiments, the precursor used to form the metal film or the metal nitride film 216 is aluminum chloride (AlCl₃). In one or more embodiments, the metal film or the metal nitride film 216 are formed using atomic layer deposition (ALD).

The metal film or the metal nitride film 216 of one or more embodiments includes a single layer. The metal film or the metal nitride film 216 is shown as a single layer in some of the Figures for simplicity and illustrative purposes, though the metal film or the metal nitride film 216 is not limited to being a single layer.

The metal film or the metal nitride film 216 of one or more embodiments includes a multilayer film 216A, 216B. The multilayer film may have any suitable number of layers in the film. In one or more embodiments, the multilayer film includes alternating layers of the same or different materials. The multilayer film includes at least two layers, e.g., a first layer 216A and a second layer 216B. In some embodiments, the first layer 216A includes the metal film comprising one or more of titanium (Ti), aluminum (Al), germanium (Ge), tantalum (Ta), zirconium (Zr), strontium (Sr), barium (Ba), or a lanthanide series metal. In some embodiments, the first layer 216A includes the metal film comprising one or more of titanium (Ti), aluminum (Al), or germanium (Ge). In some embodiments, the second layer 216B includes the metal film comprising one or more of titanium (Ti), aluminum (AI), germanium (Ge), tantalum (Ta), zirconium (Zr), strontium (Sr), barium (Ba), or a lanthanide series metal. In some embodiments, the second layer 216B includes the metal film comprising one or more of titanium (Ti), aluminum (Al), or germanium (Ge).

In some embodiments, the first layer 216A includes the metal nitride film comprising one or more of titanium nitride (TiN), aluminum nitride (AlN), germanium nitride (GeN), tantalum nitride (TaN), zirconium nitride (ZrN), strontium nitride (SrN), barium nitride (BaN), or a nitride of a lanthanide series metal. In some embodiments, the first layer 216A includes the metal nitride film comprising one or more of titanium nitride (TiN), aluminum nitride (AlN), or germanium nitride (GeN). In some embodiments, the second layer 216B includes the metal nitride film comprising one or more of titanium nitride (TIN), aluminum nitride (AlN), germanium nitride (GeN), tantalum nitride (TaN), zirconium nitride (ZrN), strontium nitride (SrN), barium nitride (BaN), or a nitride of a lanthanide series metal. In some embodiments, the second layer 216B includes the metal nitride film comprising one or more of titanium nitride (TIN), aluminum nitride (AlN), or germanium nitride (GeN).

Each of the first layer 216A and the second layer 216B have a thickness in a range of from 5 Å to 12 Å. In one or more embodiments, the multilayer film comprises a first layer 216A of aluminum nitride (AlN) with a thickness in a range of from 5 Å to 12 Å and a second layer 216B of aluminum (Al) with a thickness of 10 Å on the first layer 216A.

In one or more embodiments, the first layer 216A includes the metal film and the second layer 216B includes the metal nitride film. In specific embodiments where the first layer 216A includes the metal film and the second layer 216B includes the metal nitride film, the metal nitride film acts as a capping layer on the metal film. In specific embodiments where the first layer 216A includes the metal film and the second layer 216B includes the metal nitride film, the metal nitride film is the only capping layer in the electronic device 200. Stated differently, in specific embodiments where the first layer 216A includes the metal film and the second layer 216B includes the metal nitride film, the capping layer (e.g., the capping layer 218 comprising amorphous silicon (a-Si)) may not be present.

In specific embodiments where the first layer 216A includes the metal film and the second layer 216B includes the metal nitride film, the method 100 comprises operation 110, operation 120, operation 140, and operation 160. In one or more specific embodiments where the first layer 216A includes the metal film and the second layer 216B includes the metal nitride film, the method 100 consists essentially of operation 110, operation 120, operation 140, and operation 160. In one or more specific embodiments where the first layer 216A includes the metal film and the second layer 216B includes the metal nitride film, the method 100 consists of operation 110, operation 120, operation 140, and operation 160.

In one or more embodiments where the first layer 216A includes the metal nitride film and the second layer 216B includes the metal film 216, the titanium nitride (TIN) layer 214 is not present. Accordingly, in embodiments where the first layer 216A includes the metal nitride film and the second layer 216B includes the metal film, operation 130 is not performed. Accordingly, operation 130 of method 100 is denoted as optional. In specific embodiments, the first layer 216A including the metal nitride film is deposited directly on the high-κ dielectric layer 212, and the second layer 216B including the metal film is deposited directly on the first layer 216A.

In embodiments where the first layer 216A includes the metal nitride film and the second layer 216B includes the metal film, the method 100 comprises operation 110, operation 120, operation 140, operation 150, and operation 160. In specific embodiments, the method 100 consists essentially of operation 110, operation 120, operation 140, operation 150, and operation 160. In specific embodiments, the method 100 consists of operation 110, operation 120, operation 140, operation 150, and operation 160.

It has been advantageously found that deposition of the metal film or the metal nitride film 216, such as, for example, the multilayer film 216A, 216B on the titanium nitride (TiN) layer 214 (operation 140) reduces the thickness of the interfacial layer 210 by scavenging unbound oxygen from the interfacial layer 210 and the high-κ dielectric layer 212. The unbound oxygen from the interfacial layer 210 (e.g., silicon oxide (SiOx)) is denoted by circles having reference numeral 210-O. The unbound oxygen from the high-κ dielectric layer 212 (e.g., hafnium oxide (HfOx)) is denoted by circles having reference numeral 212-O.

Advantageously, deposition of the metal film or the metal nitride film 216, such as, for example, the multilayer film 216A, 216B on the titanium nitride (TIN) layer 214 (operation 140) reduces the thickness of the interfacial layer 210. In one or more embodiments, deposition of the metal film or the metal nitride film 216, such as, for example, the multilayer film 216A, 216B on the titanium nitride (TIN) layer 214 (operation 140) advantageously reduces the thickness by 0.15 Å to 1.5 Å. The interfacial layer having a reduced thickness is denoted by reference numeral 210′.

FIGS. 1 and 2D illustrate deposition of a capping layer 218 on the metal film or the metal nitride film 216 (operation 150). In one or more embodiments, the capping layer 218 is deposited to control oxidation after deposition.

The capping layer 218 can be any suitable material known to the skilled artisan. In one or more embodiments, the capping layer 218 comprises one or more of titanium nitride (TiN), titanium silicon nitride (TiSiN), tantalum nitride (TaN), silicon (Si), amorphous silicon (a-Si), or titanium aluminum (TiAl). In one or more embodiments, the capping layer 218 comprises amorphous silicon (α-Si). In one or more embodiments, the capping layer 218 comprises a noble metal. In one or more embodiments, the capping layer 218 comprises one or more of ruthenium (Ru), rhodium (Rh), palladium (Pd), osmium (Os), iridium (Ir), platinum (Pt), gold (Au), or silver (Ag).

In specific embodiments described herein, where the first layer 216A includes the metal film and the second layer 216B includes the metal nitride film, the capping layer 218 may not be present.

FIGS. 1 and 2E illustrate operation 160 (denoted by the arrows), which includes annealing the semiconductor substrate 202 at a temperature of less than or equal to 1050° C. In some embodiments, the temperature is in a range of from 750° C. to 1050° C. In some embodiments, at operation 160, the method 100 comprises annealing the semiconductor substrate 202 at a temperature of less than or equal to 1000° C. In some embodiments, the temperature is in a range of from 500° C. to 1000° C., including in a range of from 600° C. to 1000° C., in a range of from 700° C. to 1000° C., in a range of from 750° C. to 950° C., or in a range of from 800° C. to 900° C.

Without intending to be bound by theory, it is thought that annealing the semiconductor substrate 202 according to operation 160 promotes or accelerates the scavenging of the unbound oxygen 210-O and 212-O, respectively, from the interfacial layer 210 and the high-κ dielectric layer 212. In one or more embodiments, depending on the material selected for the metal film or metal nitride film 216, the capping layer 218 controls film oxidation after deposition.

The annealing process may be any suitable annealing process known to the skilled artisan. In one or more embodiments, the semiconductor substrate 202 is annealed at a temperature in a range of from about 700° C. to about 1050° C. In one or more embodiments, annealing the semiconductor substrate 202 at operation 160 includes a rapid thermal process (RTP). The RTP may be any suitable process known to the skilled artisan. The RTP may include a nanosecond anneal (flash anneal process) or a millisecond anneal (laser anneal process), as will be understood by the skilled artisan. The RTP includes a spike anneal process, which, in some embodiments, annealing the semiconductor substrate 202 at a temperature in a range of from about 700° C. to about 1050° C. in a nitrogen (N₂) ambient environment for 15 seconds. Without intending to be bound by theory, the RTP is believed to densify and improve the physical properties of the deposited high-κ dielectric layer 212 (the densified/annealed high-κ dielectric layer is denoted by reference numeral 212′).

In some embodiments, the method 100 includes an etching process (not illustrated) after the annealing of operation 160. The etching process can be any suitable etching process known to the skilled artisan. In some embodiments, the etching process comprises a wet etch process or a dry etch process. In some embodiments, the etching process comprises a wet etch process. In some embodiments, the wet etch process includes a pre-clean process. In some embodiments, the pre-clean process includes using one or more of ammonium hydroxide (NH₄OH) or water (H₂O). In some embodiments, the water (H₂O) is de-ionized water (DI). In some embodiments, the pre-clean process includes using a ratio of DI:NH₄OH in a range of from 100:1 DI:NH₄OH to 5:1 DI:NH₄OH.

In some embodiments, the pre-clean process includes using a SC-1 solution or a SC-2 solution. In one or more embodiments, the SC-1 solution comprises one or more of ozone, ammonium hydroxide or hydrogen peroxide. In one or more embodiments, the SC-2 solution comprises one or more of hydrochloric acid or hydrogen peroxide.

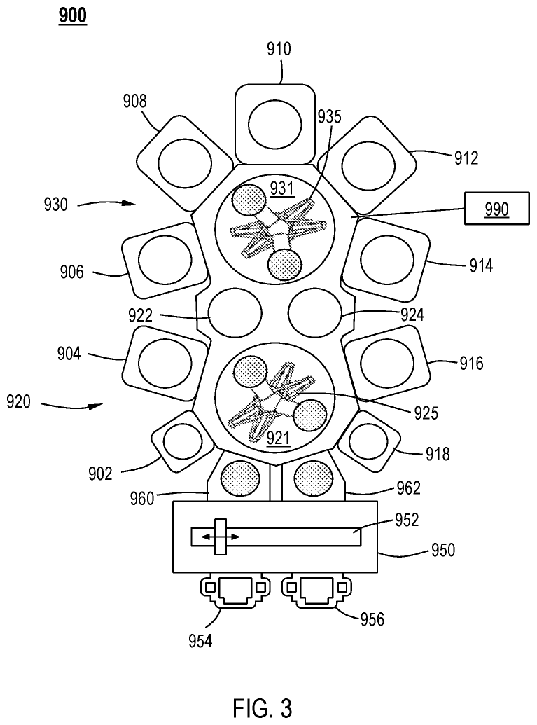

Additional embodiments of the disclosure are directed to processing tools (i.e., a cluster tool) 900 for the formation of the logic/memory devices and methods described, as shown in FIG. 3. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station 921, 931. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, a thermal processing (RTP) chamber, a plasma oxidation chamber, a plasma nitridation chamber, and an atomic layer deposition (ALD) chamber. In one or more embodiments, the ALD chamber includes a single chamber for depositing the interfacial layer 210 on the top surface 205 of the channel 206 (operation 110); depositing a high-κ dielectric layer 212 on the interfacial layer 210 (operation 120); depositing a titanium nitride (TiN) layer 214 on the high-κ dielectric layer 212 (operation 130); depositing a metal film or a metal nitride film 216 on the titanium nitride (TiN) layer 214 (operation 140); and depositing the capping layer 218 on the metal film or the metal nitride film 216 (operation 150), such that there is no vacuum break in between the operations.

In one or more embodiments, the ALD chamber can include a single chamber for each of depositing the interfacial layer 210 on the top surface 205 of the channel 206 (operation 110); depositing a high-κ dielectric layer 212 on the interfacial layer 210 (operation 120); depositing a titanium nitride (TiN) layer 214 on the high-κ dielectric layer 212 (operation 130); depositing a metal film or a metal nitride film 216 on the titanium nitride (TiN) layer 214 (operation 140); and depositing the capping layer 218 on the metal film or the metal nitride film 216 (operation 150), such that there is a vacuum break in between at least one of the operations.

The particular arrangement of processing chambers and components can be varied depending on the cluster tool and should not be taken as limiting the scope of the disclosure.

In one or more embodiments, the cluster tool 900 includes a silicon dioxide (SiO₂) chamber to deposit silicon dioxide (SiO₂). The silicon dioxide (SiO₂) deposition chamber of some embodiments comprises an atomic layer deposition chamber, a plasma enhanced atomic layer deposition chamber, or a spatial atomic layer deposition chamber. In one or more embodiments, the silicon dioxide (SiO₂) deposition chamber deposits silicon dioxide (SiO₂) by rapid thermal oxidation of silicon after pre-cleaning the substrate. In one or more embodiments, the cluster tool 900 includes a pre-cleaning chamber connected to the central transfer station.

In the embodiment shown in FIG. 3, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown in FIG. 3 has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, processing chambers 902, 904, 916, 918, and buffer chambers 922, 924. The robot 925 of some embodiments is a multi-arm robot capable of independently moving more than one wafer at a time. In one or more embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or to allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the methods, such as the method 100, of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes the processing chamber to perform the operations of any of the methods described herein. In one or more embodiments, the controller causes the processing chamber to perform one or more of the operations of the method 100.

In one or more embodiments, the cluster tool 900 comprises a central transfer station 921, 931 comprising at least one robot 925, 935 configured to move a wafer; one or more of a rapid thermal processing (RTP) station, a decoupled plasma oxidation (DPO), or decoupled plasma nitridation (DPN) station connected to the central transfer station; an atomic layer deposition (ALD) station connected to the central transfer station; an optional pre-clean station connected to the central transfer station; and at least one controller connected to the one or more of the central transfer station, the RTP station, the DPO station, the DPN station, the ALD station or the optional pre-clean station. In one or more embodiments, the at least one controller has at least one configuration selected from: a configuration to move the wafer between stations using the robot; a configuration to perform a rapid thermal process; a configuration to perform a decoupled plasma process; a configuration to control a flow of an oxidizing gas into the RTP station or DPO station; a configuration to control a flow of a nitriding gas into the RTP station or DPN station; a configuration to deposit a silicon oxide film by atomic layer deposition; and a configuration to pre-clean the wafer.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Comparative Example 1

A metal gate stack was formed on a silicon substrate. The metal gate stack includes an interfacial layer comprising silicon oxide (SiOx) on the semiconductor substrate, a high-κ dielectric layer on the interfacial layer, a titanium nitride (TiN) layer on the high-κ dielectric layer, and a capping layer comprising amorphous-silicon (α-Si) on the titanium nitride (TiN) layer. The metal gate stack was then annealed using a rapid thermal process (RTP) at a temperature in a range of from about 700° C. to about 1050° C. using a rapid thermal process (RTP) in a nitrogen (N₂) ambient environment for 15 seconds. The metal gate stack exhibited a reduction in the thickness of the interfacial layer of about 0.1 Å.

### Inventive Example 1

A metal gate stack was formed on a silicon substrate following the operations of method 100. The metal gate stack includes an interfacial layer comprising silicon oxide (SiOx) and a thickness in a range of from 8 Å to 10 Å on the semiconductor substrate, a high-κ dielectric layer comprising hafnium oxide (HfOx) and a thickness in a range of from 10 Å to 20 Å on the interfacial layer, a titanium nitride (TiN) layer having a thickness in a range of 0 Å to 20 Å on the high-κ dielectric layer, a metal film or a metal nitride film on the titanium nitride (TiN) layer, the metal film or the metal nitride film including a multilayer film, and a capping layer comprising amorphous silicon (α-Si) and a thickness in a range of 0 Å to 20 Å on the metal film or the metal nitride film. The metal gate stack was then annealed using a rapid thermal process (RTP) in a range of from about 700° C. to about 1050° C. using a rapid thermal process (RTP) in a nitrogen (N₂) ambient environment for 15 seconds, which is the same RTP used in Comparative Example 1.

It was advantageously found that the multilayer film reduced the thickness of the interfacial layer by scavenging unbound oxygen from the interfacial layer and the high-κ dielectric layer. In specific examples, when the multilayer film included a metal film having a thickness in a range of from 5 Å to 12 Å and a metal film having a thickness in a range of from 5 Å to 12 Å, the multilayer film reduced the thickness of the interfacial layer by 0.15 Å to 1.5 Å. Accordingly, the metal gate stack formed by method 100 exhibited improved interfacial layer scaling compared to the metal gate stack formed in Comparative Example 1. Advantageously, the metal gate stack formed by method 100 exhibited reduced equivalent oxide thickness (EOT).

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing an electronic device, the method comprising:
depositing an interfacial layer on a top surface of a channel located between a source and a drain on a semiconductor substrate;
depositing a high-κ dielectric layer on the interfacial layer;
depositing a titanium nitride (TiN) layer on the high-κ dielectric layer;
depositing a metal film or a metal nitride film on the titanium nitride (TIN) layer; and
depositing a capping layer on the metal film or the metal nitride film.

2. The method of claim 1, wherein the interfacial layer comprises silicon oxide (SiOx).

3. The method of claim 1, wherein the interfacial layer has a thickness in a range of from 8 Å to 11 Å.

4. The method of claim 1, wherein the high-κ dielectric layer comprises one or more of hafnium oxide (HfOx), hafnium zirconium oxide (HfZrOx), zirconium oxide (ZrOx), nitrogen-doped hafnium oxide (HfOx), nitrogen-doped hafnium zirconium oxide (HfZrOx), and nitrogen-doped zirconium oxide (ZrOx).

5. The method of claim 1, wherein the high-κ dielectric layer has a thickness in a range of from 10 Å to 20 Å.

6. The method of claim 1, wherein one or more of the metal film or the metal nitride film comprises a multilayer film.

7. The method of claim 6, wherein the electronic device comprises the metal film and the metal film is selected from one or more of titanium (Ti), aluminum (AI), germanium (Ge), tantalum (Ta), zirconium (Zr), strontium (Sr), barium (Ba), or a lanthanide series metal.

8. The method of claim 6, wherein the electronic device comprises the metal nitride film and the metal nitride film is selected from one or more of titanium nitride (TIN), aluminum nitride (AlN), germanium nitride (GeN), tantalum nitride (TaN), zirconium nitride (ZrN), strontium nitride (SrN), barium nitride (BaN), or a nitride of a lanthanide series metal.

9. The method of claim 6, wherein the multilayer film comprises a first layer of aluminum nitride (AlN) and a second layer of aluminum (Al) on the first layer.

10. The method of claim 9, wherein the first layer has a thickness in a range of from 5 Å to 12 Å and the second layer has a thickness in a range of from 5 Å to 12 Å.

11. The method of claim 10, wherein the multilayer film reduces the thickness of the interfacial layer by scavenging unbound oxygen from the interfacial layer and the high-κ dielectric layer.

12. The method of claim 11, wherein the multilayer film reduces the thickness of the interfacial layer by 0.15 Å to 1.5 Å.

13. The method of claim 1, wherein the capping layer comprises amorphous silicon (α-Si).

14. The method of claim 1, wherein the capping layer is deposited in situ.

15. The method of claim 1, wherein depositing the metal film or the metal nitride film comprises exposing the semiconductor substrate to a pulse of a metal-containing precursor and a pulse of a reactant by an atomic layer deposition (ALD) process or a chemical vapor deposition (CVD) process.

16. The method of claim 11, further comprising annealing the semiconductor substrate at a temperature of less than or equal to 1050° C. to accelerate the scavenging.

17. A method of manufacturing an electronic device, the method comprising:
depositing an interfacial layer comprising silicon oxide (SiOx) and a thickness in a range of from 8 Å to 10 Å on a top surface of a channel located between a source and a drain on a semiconductor substrate;
depositing a high-dielectric layer comprising hafnium oxide (HfOx) and a thickness in a range of from 10 Å to 20 Å on the interfacial layer;
depositing a titanium nitride (TiN) layer having a thickness in a range of 0 Å to 20 Å on the high-κ dielectric layer;
depositing a metal film or a metal nitride film on the titanium nitride (TIN) layer, the metal film or the metal nitride film including a multilayer film, the multilayer film reducing the thickness of the interfacial layer by scavenging unbound oxygen from the interfacial layer and the high-κ dielectric layer;
depositing a capping layer comprising amorphous silicon (α-Si) and a thickness in a range of 0 Å to 20 Å on the metal film or the metal nitride film; and
annealing the semiconductor substrate at a temperature of less than or equal to 1050° C. to accelerate the scavenging.

18. The method of claim 17, wherein the multilayer film includes a first layer of aluminum nitride (AlN) and a second layer of aluminum (Al) on the first layer.

19. The method of claim 18, wherein the first layer has a thickness in a range of from 5 Å to 12 Å and the second layer has a thickness in a range of from 5 Å to 12 Å.

20. The method of claim 19, wherein the multilayer film reduces the thickness of the interfacial layer by 0.15 Å to 1.5 Å.
